(19) United States
(12) Patent Application Publication
(10) Pub. No.: US 2009/0159883 A1
(43) Pub. Date: Jun. 25, 2009

(54) TEST PATTERN FOR SEMICONDUCTOR DEVICE AND METHOD FOR FORMING THE TEST PATTERN

(76) Inventor: Choon-Ho Lee, Yongin-si (KR)

Correspondence Address: SHERR & VAUGHN, PLLC, 620 HERNDON PARKWAY, SUITE 200, HERNDON, VA, 20170, US

(21) Appl. No.: 12/334,497

(22) Filed: Dec. 14, 2008

(30) Foreign Application Priority Data
Dec. 24, 2007 (KR) 10-2007-0136245

(51) Int. Cl. H01L 23/58; H01L 23/48; H01L 21/44

(52) U.S. Cl. 257/48; 257/773; 438/672; 257/E23.002; 257/E23.168; 257/E21.577

(57) ABSTRACT

A test pattern for a semiconductor device and a method for forming the test pattern that can determine the degree of over etching of contact holes and obviate the need to perform a physical analysis using SEM, FIB or the like after the wafer is destroyed.

The present application claims priority under 35 U.S.C. §119 to Korean Patent Application No. 10-2007-0136245 (filed on Dec. 24, 2007), which is hereby incorporated by reference in its entirety.

### BACKGROUND

In the fabrication of a semiconductor device, after every process is completed by forming various test patterns on and/or over a scribe lane in order to determine whether each process is accurate and whether characteristics of unit devices (i.e., transistor, capacitor, metal wire, via contact and the like) are formed properly, the electrical characteristics in the corresponding patterns are tested. There is demand for a test pattern which determines whether a contact is opened when a metal wire is formed. In such a test pattern, a contact is arranged in a chain type and current flow is measured using two terminals and its resistance values are calculated, thereby determining whether the process is accurate.

FIGS. 1 and 2 illustrate a related test pattern for measuring whether a contact is opened. As shown in FIGS. 1 and 2, an active region and a field region are defined in a semiconductor substrate 1 such that a field oxide layer or a device isolation layer STI 2 is formed in the field region. A plurality of lower conductive layers 3 are formed in a zigzag island shape in the active region through an impurity ion-implantation or the like. An interlayer insulating layer 4 is formed on and/or over the substrate 1 including the lower conductive layers 3. A plurality of contact holes are formed in the interlayer insulating layer 4 on and/or over a respective lower conductive layer 3. Contact plugs 5 are then formed in the contact holes so as to be electrically connected to the lower conductive layers 3. Upper conductive layers 6 connecting electrically the respective lower conductive layers 3 through the contact plugs 5 are formed on and/or over the interlayer insulating layer 4. The upper conductive layer 6 positioned at the distal end may be used as a pad.

An overall number of contact plugs formed may be at least a thousand. With a method for forming the contact holes, a photoresist film is deposited on and/or over the interlayer insulating layer 4 and is patterned through exposure and development processes to expose portions of the interlayer insulating layer 4 where contact holes are to be formed. The interlayer insulating layer 4 is then etched using the patterned photoresist film as a mask to thereby expose the lower conductive layers 3. The interlayer insulating layer 4 is over-etched in a range between approximately 150 to 200% so that the interlayer insulating layer 4 is sufficiently removed. Therefore, the resistance values are measured by allowing current to be flowed between first and second pads to determine whether the contact is opened. However, when such a test pattern is used, the depth of the contact hole is the same in all regions, causing a problem that the degree of over-etching cannot be determined through an electrical measuring method.

### SUMMARY

During formation of a semiconductor device such as a flash memory device, a common source wire is not formed on and/or over an uppermost surface of a substrate but in the substrate through an impurity ion-implantation process in order to reduce cell size. In other words, in order to manufacture such a flash memory device, an active region and a field region are defined in a semiconductor substrate and a trench is formed in the field region. The trench is filled with an insulating layer such as an oxide layer or the like to form a device isolation film, thereby insulating the active region from the active region. A tunneling oxide layer is then formed on and/or over the semiconductor substrate and a floating gate is formed on and/or over the tunneling oxide layer in each active region. A dielectric layer is then formed on and/or over the substrate including the floating gate, and a control gate line (word line) is formed on and/or over the dielectric layer. The control gate line is formed to overlap the plurality of floating gates formed in one direction. The device isolation layer between the control gate lines are selectively removed and an impurity ion is implanted into a portion that is, a trench region, where the device isolation layer is removed, thereby forming a common source wire. In consideration of the common source wire of such a flash memory device, in accordance with embodiments, lower conductive layers are formed at different heights in order to vary the depths of the contact holes.

The semiconductor substrate in the test pattern of the semiconductor device in accordance with embodiments is defined having a plurality of regions such that at least one of the regions has a trench structure formed at varying depths. The lower conductive layers are spaced in the plurality of regions, and an interlayer insulating layer is formed on and/or over the substrate including the lower conductive layers. A plurality of contact plugs are formed in the interlayer insulating layer on and/or over and electrically connected to a respective lower conductive layer. Upper conductive layers are formed on and/or over the interlayer insulating layer and electrically connected to the lower conductive layers through the contact plugs.

Embodiments relate to a semiconductor device and a method for manufacturing the same, and more particularly, to a test pattern for measuring the degree of over-etching of a contact and a method for forming the test pattern.

Embodiments relate to a test pattern for a semiconductor device and a method for forming the test pattern that can determine whether an over-etching is normally performed when a contact hole is formed by forming at least two lower conductive layers at different heights and at least two contact holes having different depths, considering that a common source line is formed in a trench region in order to reduce a cell size in a flash memory.

Embodiments relate to a test pattern of a semiconductor device that may include at least one of the following: a semiconductor substrate defined with a plurality of regions, at least one of the regions having a trench structure formed at different depths; a plurality of lower conductive layers formed spaced apart on and/or over the regions; an interlayer insulating layer formed on and/or over the substrate including the lower conductive layers; a plurality of contact plugs formed on and/or over the interlayer insulating layer and connected electrically to a respective lower conductive layer; and a plurality of upper conductive layers formed on and/or over the interlayer insulating layer electrically connected to a respective lower conductive layer through the contact plugs.

Embodiments relate to a test pattern of a semiconductor device that may include at least one of the following: a semiconductor substrate having a plurality of regions, at least one region having a trench formed therein; a lower conductive layer formed at the regions such that the at least one region has a lower conductive layer formed in the semiconductor substrate; an interlayer insulating layer formed over the semiconductor substrate including each lower conductive layer; a plurality of contact plugs formed spaced apart in the interlayer insulating layer and connected electrically to a respective lower conductive layer; and an upper conductive layer formed over the interlayer insulating layer and electrically connected to a respective lower conductive layer through the contact plugs.

Embodiments relate to a test pattern of a semiconductor device that may include at least one of the following: a semiconductor substrate having a plurality of regions including a first region and a second region formed spatially below the first region; a lower conductive layer formed at the first region over the uppermost surface of the semiconductor substrate and at the at the second region in the semiconductor substrate; an interlayer insulating layer formed over each lower conductive layer; a pair of contact plugs formed spaced apart in the interlayer insulating layer and connected electrically to a respective lower conductive layer; and an upper conductive layer formed over the interlayer insulating layer and electrically connected to a respective lower conductive layer through the contact plugs.

Embodiments relate to a method for forming a test pattern of a semiconductor device that may include at least one of the following: forming trenches having different depths in a semiconductor substrate; forming a plurality of lower conductive layers spaced apart on and/or over the substrate; forming an interlayer insulating layer on and/or over the substrate including the lower conductive layers; forming a plurality of contact holes in the interlayer insulating layer and on and/or over a respective lower conductive layer; forming a plurality of contact plugs in the contact holes to be connected electrically to a respective lower conductive layer; and then forming a plurality of upper conductive layers on and/or over the interlayer insulating layer and electrically connected to a respective lower conductive layer through the contact plugs.

Embodiments relate to a method that may include at least one of the following: providing a semiconductor substrate having a plurality of regions; and then forming a trench in at least one of the regions; and then forming a lower conductive layer at the regions such that the at least one of the regions has a lower conductive layer formed in the semiconductor substrate; and then forming an interlayer insulating layer over the semiconductor substrate including each lower conductive layer; and then forming a plurality of contact holes spaced apart in the interlayer insulating layer exposing the a respective lower conductive layer; and then forming a contact plug spaced apart in the contact holes and connected electrically to a respective lower conductive layer; and then forming an upper conductive layer over the interlayer insulating layer and electrically connected to a respective lower conductive layer through the contact plug.

### DRAWINGS

FIGS. 1 and 2 illustrate a test pattern of a semiconductor device.

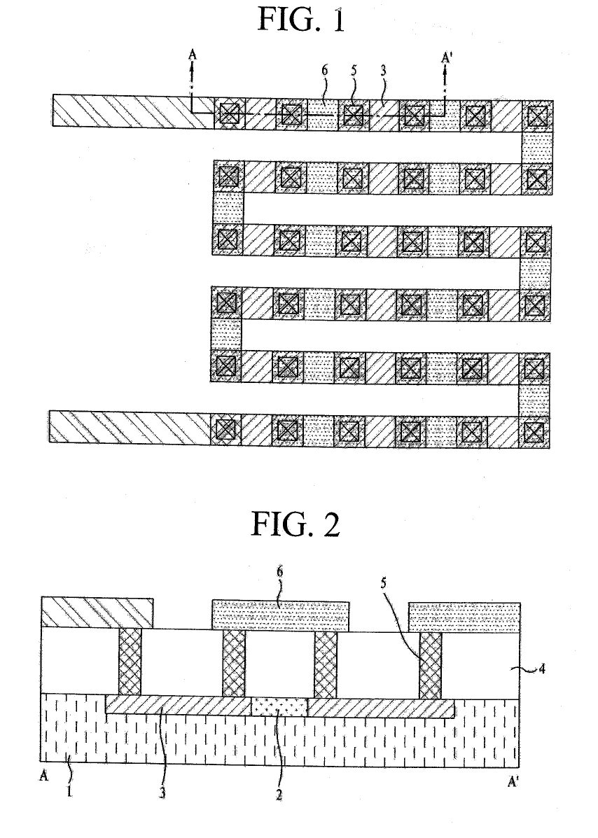

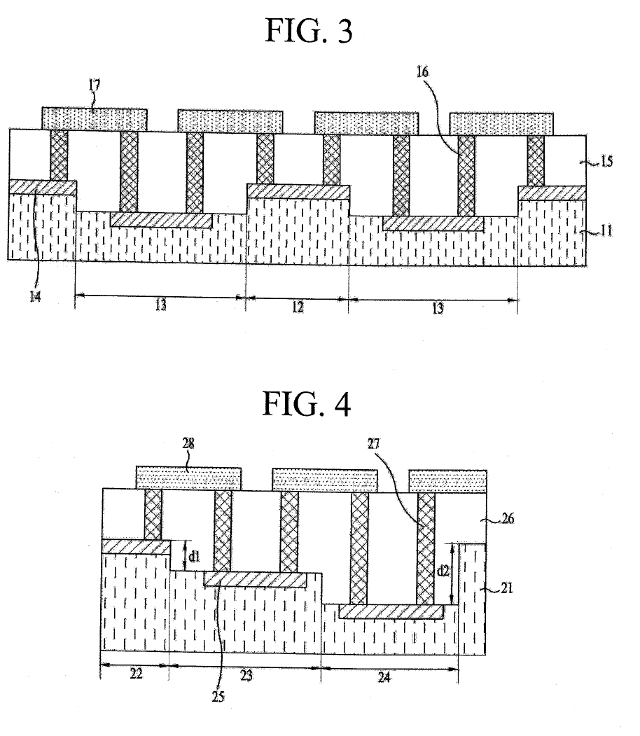

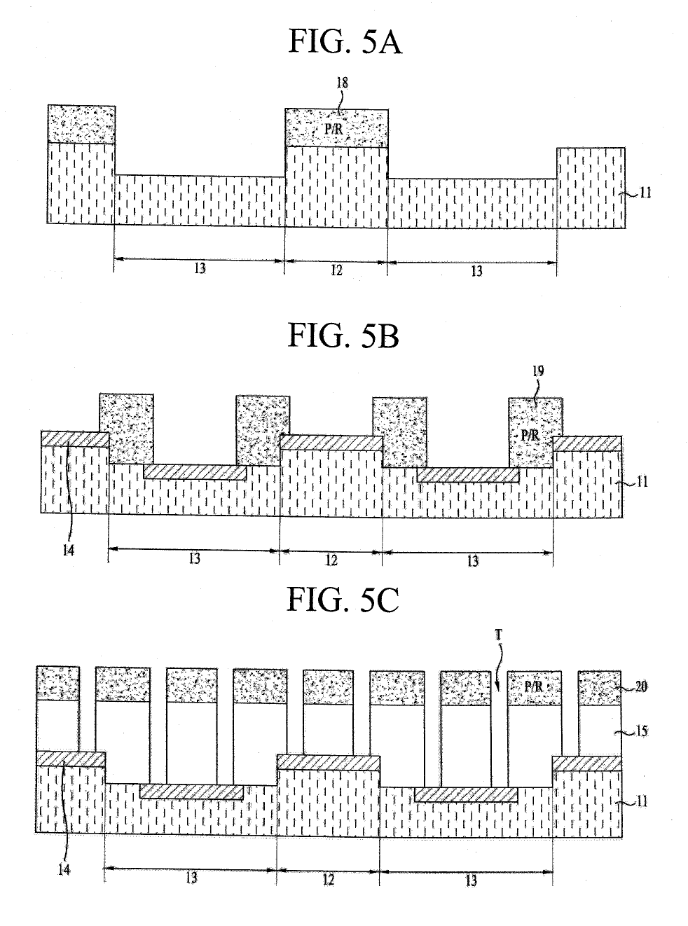

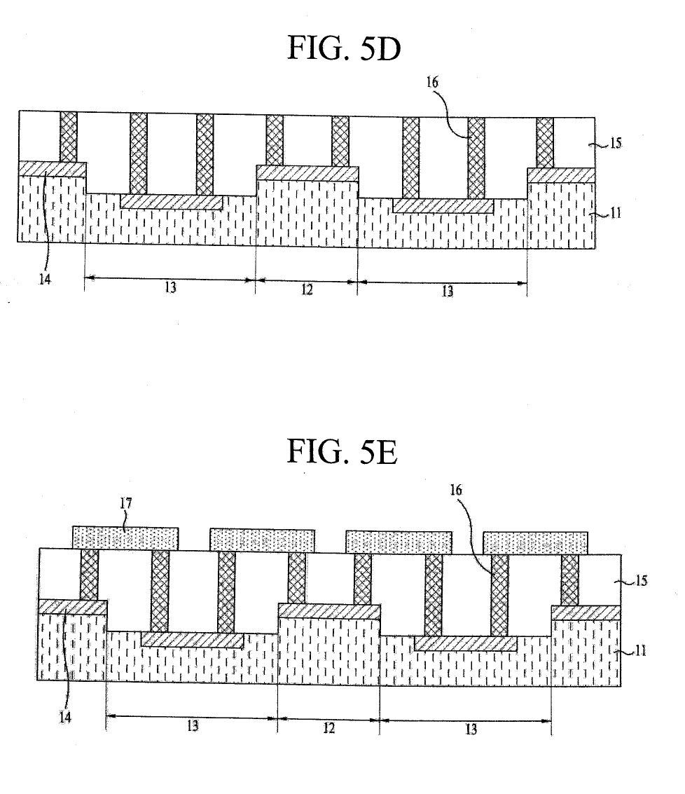

Example FIGS. 3 to 5 illustrate a test pattern of a semiconductor device and a method for forming a test pattern of a semiconductor device in accordance with embodiments.

### DESCRIPTION

In accordance with embodiments, in order to assist the understanding of the test pattern of a semiconductor device, a test pattern may include a substrate having a plurality of regions such as a first region and a second region. The second region has a trench structure, and lower conductive layers are formed spaced apart on and/or over the first region and the second region.

Example FIG. 3 is a cross-sectional view of a test pattern of a semiconductor device in accordance with embodiments. As shown in example FIG. 3, a semiconductor substrate 11 is defined having a plurality of regions including first regions 12 and second regions 13 formed in series. The surface of each second region 13 is etched to a predetermined depth to form a trench. The second region 13 where the trench is formed corresponds to a common source wire region of the flash memory source.

A lower conductive layer 14 is formed on and/or over each first region 13. A lower conductive layer 14 is also formed at each trench and in the substrate 11 such that the lower conductive layers 14 formed in the first region 12 are formed spatially above the lower conductive layers 14 formed in the second region 13. The lower conductive layers 14 may be formed by an impurity ion implantation. The plurality of lower conductive layers 14 are formed in a zigzag island shape.

An interlayer insulating layer 15 is then formed on and/or over the substrate 11 including the lower conductive layers 14. A plurality of contact holes are formed in the interlayer insulating layer 15 on and/or over a respective lower conductive layer 14. The contact holes may be formed by forming a photoresist film on and/or over the interlayer insulating layer 15 and is then patterned through exposure and development processes to expose portions of the interlayer insulating layer 15 where contact holes are to be formed. The interlayer insulating layer 15 is then etched using the patterned photoresist film as a mask to expose the lower conductive layers 14. The interlayer insulating layer 15 may be over-etched in a range between approximately 150 to 200% so that the interlayer insulating layer 15 is sufficiently removed.

Contact plugs 16 are then formed in the contact holes and connected electrically to the lower conductive layers 14. An upper conductive layer 17 electrically connected to a respective lower conductive layer 14 through the contact plugs 16 is then formed on and/or over the interlayer insulating layer 15. The distal most upper conductive layers 17 may be used as a pad. Accordingly, resistance values may then are measured by allowing current flow between the outermost lower conductive layers 14 (i.e., those serving as pads) to determine whether the contact is opened.

Example FIG. 4 illustrates a test pattern of a semiconductor device in accordance with embodiments. As shown in example FIG. 4, in a test pattern of a semiconductor device, a semiconductor substrate 21 is defined having a plurality of regions including first regions 22 formed at a first height, second regions 23 formed at a second height lower than the first height and third regions 24 formed at a third height lower than the second height. The surface of each second region 23 is etched to a predetermined depth d1 to form a trench at the predetermined depth d1 in the semiconductor substrate 21. The surface of each third region 24 is etched to a second predetermined depth d2 to form a trench at the second predetermined depth d2 of the semiconductor substrate 21. The first depth d1 is greater than the second depth d2. One of the second region 23 and the third region 24 where the trench is formed may correspond to a common source wire region of the flash memory source.

A lower conductive layer 25 is formed at the first region 22 on and/or over the substrate 22, and also at the second region 23 and the third region 24 in the substrate 21. The lower conductive layers 25 may be formed by an impurity ion implantation. The plurality of lower conductive layers 25 are formed in a zigzag island shape. An interlayer insulating layer 26 is then formed on and/or over the substrate 21 including the plurality of lower conductive layers 25. A plurality of contact holes are formed in the interlayer insulating layer 26 exposing a respective lower conductive layer 25. The contact holes may be formed by forming a photoresist film on and/or over the interlayer insulating layer 26 and is then patterned through exposure and development processes to expose portions of the interlayer insulating layer 26 where the contact holes are to be formed. The interlayer insulating layer 26 is then etched using the patterned photoresist film as a mask to expose portions of each lower conductive layer 25. The interlayer insulating layer 26 may be over-etched in a range between approximately 150 to 200% so that the interlayer insulating layer 26 is sufficiently removed.

Contact plugs 27 are formed in the contact holes connected electrically to a respective lower conductive layer 25. An upper conductive layer 28 electrically connected to a respective lower conductive layer 25 through the contact plugs 27 is then formed on and/or over the interlayer insulating layer 26. The distal upper conductive layers 28 may be used as a pad. Therefore, resistance values may be measured by allowing current flow between the pads to thereby determine whether the contact is opened.

Example FIGS. 5A to 5E are cross-sectional views showing a method for forming a test pattern of a semiconductor device in accordance with embodiments.

As shown in example FIG. 5A, a semiconductor substrate 11 is defined having a plurality of first regions 12 and second regions 13. A photoresist film 18 is deposited on and/or over the semiconductor substrate 11 and is patterned by performing exposure and development processes to expose the second region 13. The second region 13 of the semiconductor substrate 11 is then selectively etched using the patterned first photoresist film 18 as a mask, thereby forming a first trench.

As shown in example FIG. 5B, after the first photoresist film 18 is removed, a second photoresist film 19 is formed on and/or over region the semiconductor substrate 11 on which the trench is formed and is patterned to remain only at an interface between the first region 12 and second region 13 by performing exposure and development processes. A lower conductive layer 14 is formed by implanting high-concentration impurity ions into the first region 12 and the second region 13 of the semiconductor substrate 11 using the patterned second photoresist film 19 as a mask.

As shown in example FIG. 5C, the second photoresist film 19 is then removed, and an interlayer insulating layer 15 is formed on and/or over the substrate 11 including the lower conductive layer 14. A third photoresist film 20 is then deposited and patterned so that the interlayer insulating layer 15 corresponding to both regions of the respective lower conductive layers 14 are exposed by performing exposure and development processes. A plurality of contact holes T are formed in the interlayer insulating layer 15 spaced apart and exposing a respective lower conductive layer 14 by etching the interlayer insulating layer 15 using the patterned third photoresist film 20 as a mask. For forming the contact holes T, the interlayer insulating layer 15 is over etched in a range between approximately 150 to 200% of the thickness of the interlayer insulating layer 15.

As shown in example FIG. 5D, a metal layer (tungsten or the like) is then deposited so as to gap-fill the plurality of contact holes T and a chemical mechanical polishing (CMP) process is performed to form contact plugs 16 in the contact holes T connected electrically to the lower conductive layers 14.

As shown in example FIG. 5E, a metal layer is then deposited and selectively removed on and/or over the interlayer insulating layer 15 to form the upper conductive layers 17 to connect electrically to a respective lower conductive layer 14 through the contact plugs 16.

A method for forming a test pattern of a semiconductor device in accordance with embodiments is similar embodiments illustrated in example FIGS. 5A to 5E, and includes a substrate having a plurality of regions such as a first region, a second region and a third region. The surfaces of the second region and third region are selectively etched to form trenches having different depths, particularly, the third region is formed spatially below the second region, which in turn, is formed below the first region. Lower conductive layers are formed on and/or over the uppermost surface of the substrate at the first region and also formed in the substrate at the second region and the third region.

In accordance with embodiments, when over etching for forming contact holes are not made as desired, an opening occurs in the lower conductive layers 14 and 25 formed in the trench region (second and third regions) and at this time, the measured resistance will be represented by giga ohm unit. It is possible to determine whether the over etch is normally performed without destroying a wafer, using the measured resistance.

Accordingly, a method for forming a test pattern of a semiconductor device in accordance with embodiments includes a semiconductor substrate is defined as a plurality of regions and at least one surface of the plurality of regions is selective etched to form a trench having different depths. Thereafter, a plurality of lower conductive layers are formed to be spaced on each region. Thereafter, an interlayer insulating layer is formed overall the substrate on which the plurality of lower conductive layers are formed. Thereafter, a plurality of contact holes are formed on the interlayer insulating layer on both sides of the respective lower conductive layers. Thereafter, a plurality of contact plugs are formed within the plurality of contact holes to be connected electrically to the respective lower conductive layers. Thereafter, a plurality of upper conductive layers are formed on the interlayer insulating layer to connect the respective lower conductive layers electrically through the contact plugs.

With the test pattern and the method for forming the test pattern in accordance with embodiments, the lower conductive layers formed on the substrate are formed having different steps, instead of having the same height, to form contact holes having different depths, making it possible to check the degree of over etch of the contact holes. Therefore, embodiments can save time, since there is no need to perform a physical analysis using SEM, FIB or the like after the wafer is destroyed.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a semiconductor substrate having a plurality of regions, at least one region having a trench formed therein;
a lower conductive layer formed at the regions, wherein the at least one region has a lower conductive layer formed in the semiconductor substrate;
an interlayer insulating layer formed over the semiconductor substrate including each lower conductive layer;
a plurality of contact plugs formed spaced apart in the interlayer insulating layer and connected electrically to a respective lower conductive layer; and
an upper conductive layer formed over the interlayer insulating layer and electrically connected to a respective lower conductive layer through the contact plugs.

2. The apparatus of claim 1, wherein the plurality of regions comprises a first region and a second region such that the second region has the trench.

3. The apparatus of claim 1, wherein the second region corresponds to a common source wire region of a device.

4. The apparatus of claim 3, wherein the device comprises a flash memory device.

5. The apparatus of claim 1, wherein the plurality of regions comprises a first region, a second region and a third region such that the second region and the third region have the trench.

6. The apparatus of claim 5, wherein the first region is formed at a first height, the second region is formed at a second height lower than the first height and the third region is formed at a third height lower than the second height and the first height.

7. The apparatus of claim 5, wherein at least one of the second region and the third region corresponds to a common source wire region of a device.

8. The apparatus of claim 7, wherein the device comprises a flash memory device.

9. A method comprising:
providing a semiconductor substrate having a plurality of regions; and then
forming a trench in at least one of the regions; and then
forming a lower conductive layer at the regions, wherein the at least one of the regions has a lower conductive layer formed in the semiconductor substrate; and then
forming an interlayer insulating layer over the semiconductor substrate including each lower conductive layer; and then
forming a plurality of contact holes spaced apart in the interlayer insulating layer exposing the a respective lower conductive layer; and then
forming a contact plug spaced apart in the contact holes and connected electrically to a respective lower conductive layer; and then
forming an upper conductive layer over the interlayer insulating layer and electrically connected to a respective lower conductive layer through the contact plug.

10. The method of claim 9, wherein the plurality of regions comprises a first region and a second region.

11. The method of claim 10, wherein forming the trench comprises forming a trench in the second region.

12. The method of claim 11, wherein the second region corresponds to a common source wire region of a device.

13. The method of claim 12, wherein the device comprises a flash memory device.

14. The method of claim 9, wherein the plurality of regions comprises a first region, a second region and a third region.

15. The method of claim 14, wherein forming the trench comprises forming a trench in the second region and the third region.

16. The method of claim 15, wherein the trench in the second region is formed at a first depth and the trench in the third region is formed at a second depth greater than the first depth.

17. The method of claim 14, wherein at least one of the second region and the third region corresponds to a common source wire region of a device.

18. The method of claim 17, wherein the device comprises a flash memory device.

19. An apparatus comprising:
a semiconductor substrate having a plurality of regions including a first region and a second region formed spatially below the first region;
a lower conductive layer formed at the first region over the uppermost surface of the semiconductor substrate and at the at the second region in the semiconductor substrate;
an interlayer insulating layer formed over each lower conductive layer;
a pair of contact plugs formed spaced apart in the interlayer insulating layer and connected electrically to a respective lower conductive layer; and
an upper conductive layer formed over the interlayer insulating layer and electrically connected to a respective lower conductive layer through the contact plugs.

20. The apparatus of claim 19, further comprising a third region formed spatially below the second region, wherein a lower conductive layer is formed at the third region and in the semiconductor substrate.
